(19) United States
(12) Patent Application Publication
(10) Pub. No.: US 2026/0029290 A1
(43) Pub. Date: Jan. 29, 2026

(54) METHOD, APPARATUS AND SYSTEM FOR TESTING INERTIA COEFFICIENT AND DAMPING COEFFICIENT OF GRID-FORMING CONVERTER

(71) Applicant: Shandong University, Jinan (CN)

(72) Inventors: Jingyang FANG, Jinan (CN); Yufan WANG, Jinan (CN); Wenjia SI, Jinan (CN); Kailong LIU, Jinan (CN); Feng GAO, Jinan (CN); Hao TIAN, Jinan (CN); Tao XU, Jinan (CN); Chunna YU, Jinan (CN)

(73) Assignee: Shandong University, Jinan (CN)

(21) Appl. No.: 19/276,066

(22) Filed: Jul. 22, 2025

(30) Foreign Application Priority Data
Jul. 25, 2024 (CN) 202411006688.4

(51) Int. Cl. G01M 1/10; G01R 21/00; G01R 23/02

(52) U.S. Cl. CPC G01M 1/10; G01R 21/001; G01R 23/02

(57) ABSTRACT

Provided are a method, an apparatus, and a system for testing an inertia coefficient and a damping coefficient of a grid-forming converter. The method includes: obtaining a filter capacitor voltage in a three-phase inductor-capacitor-inductor (LCL) filter, an inverter-side current, an output-side current, and an output three-phase voltage; outputting a frequency output signal and a phase output signal through frequency control; outputting a pulse width modulation (PWM) control signal based on the phase output signal, the filter capacitor voltage, and the inverter-side current, to control turn-on time of a power semiconductor switch; outputting an active power signal; processing the output three-phase voltage to obtain a real-time output frequency; obtaining the damping coefficient of the grid-forming converter based on the active power signal, the frequency output signal, and a related setting parameter; and obtaining the inertia coefficient of the grid-forming converter.

### CROSS REFERENCE TO THE RELATED APPLICATIONS

This application is based upon and claims priority to Chinese Patent Application No. 202411006688.4, filed on Jul. 25, 2024, the entire contents of which are incorporated herein by reference.

### TECHNICAL FIELD

The present disclosure pertains to the technical field of grid-forming converters in power electronics, and in particular, relates to a method, an apparatus and a system for testing an inertia coefficient and a damping coefficient of a grid-forming converter.

### BACKGROUND

This section is merely intended to provide background information related to the present disclosure, and does not necessarily constitute the conventional technology.

With a rising proportion of renewable energy in modern power grids, frequency stability issues are becoming more serious. A system inertia and a fast frequency response capability are enhanced by a grid-forming converter by stimulating a mechanical inertia, and a damping service is provided to maintain power grid stability. In an islanded operation mode, the grid-forming converter can be operated as a voltage source model to establish a power grid and enable black start. By providing fast and precise ancillary services, reliance of the power grid on a conventional backup power generator can be reduced by the grid-forming converter, to enhance both economic efficiency and reliability of power grid operation.

An inertia coefficient and a damping coefficient of the grid-forming converter are critical to the power grid, yet related test means remain undefined. Testing the inertia coefficient and the damping coefficient of the grid-forming converter enables accurate assessment of grid-forming converters designed by various manufacturers while ensuring strict compliance with power grid interconnection standards and technical specifications, thereby ensuring security and reliability of the power grid. In addition, test results further can provide valid references for formulating compensation policies in the ancillary service market, thereby promoting evidence-based and equitable decision-making, accelerating technological advancement, promoting market competition, and ultimately enhancing overall stability and cost efficiency of a power system.

An existing inertia and damping test method includes: Inertia and damping of a system are tested based on a second-order rotor angle transfer function and an active power response curve. An internal relation between the inertia, a characteristic value, and a characteristic vector is analyzed by using a linear dynamic equation, to deduce the inertia through a detailed mathematical expression. Alternatively, inertia and damping of a power system are estimated by a phase measurement unit according to an environmental frequency for phase measurement and an active power signal. Alternatively, a cost function based on a swing equation is optimized by using an algorithm, for example, particle swarm optimization, to achieve estimation, and the like on the damping and the inertia of the power system. However, the foregoing method is mainly applied to the power system instead of the grid-forming converter, and has problems such as a complex mathematical model, difficulty in inertia and damping decoupling, and the like.

### SUMMARY

To overcome the disadvantages in the conventional technology, the present disclosure provides a method for testing an inertia coefficient and a damping coefficient of a grid-forming converter. In a practical application, the method features high feasibility, a simple and effective implementation principle, case of implementation, and a scalable application.

To achieve the foregoing objective, one or more embodiments of the present disclosure provide the following technical solutions.

According to a first aspect, a method for testing an inertia coefficient and a damping coefficient of a grid-forming converter is provided, including:
obtaining a filter capacitor voltage in a three-phase inductor-capacitor-inductor (LCL) filter, an inverter-side current, an output-side current, and an output three-phase voltage;
outputting a frequency output signal and a phase output signal through frequency control;
outputting a pulse width modulation (PWM) control signal based on the phase output signal, the filter capacitor voltage, and the inverter-side current, to control turn-on time of a power semiconductor switch;
outputting an active power signal based on the output three-phase voltage, the output-side current, and the phase output signal;
processing the output three-phase voltage to obtain a real-time output frequency;
obtaining the damping coefficient of the grid-forming converter based on the active power signal, the frequency output signal, and a related setting parameter; and
obtaining the inertia coefficient of the grid-forming converter based on the active power signal, the real-time output frequency, and a related setting parameter.

In a further technical solution, the outputting a frequency output signal and a phase output signal through frequency control specifically includes:
generating, by a step signal generator, a frequency change rate input signal; and
integrating the frequency change rate input signal with a reference frequency input signal for calculation, and obtaining both the frequency output signal and the phase output signal, where

the phase output signal is used for voltage control and active power measurement, and the frequency output signal is used for measurement of the damping coefficient.

In a further technical solution, the outputting a PWM control signal based on the phase output signal, the filter capacitor voltage, and the inverter-side current specifically includes:
sampling the filter capacitor voltage and the inverter-side current, and performing abc-to-dq transformation on a sampling signal to obtain a d-axis component v_{tfd} and a q-axis component v_{tfq} of the sampled filter capacitor voltage, and a d-axis component i_{tid} and a q-axis component i_{tiq} of the sampled inverter-side current;
integrating v_{tfd} and v_{tfq} with a d-axis reference value v_{tfd_ref} and a q-axis reference value v_{tfq_ref} of an input capacitor voltage, and obtaining a d-axis reference value i_{tid_ref} and a q-axis reference value i_{tiq} ref of the inverter-side current through calculation and proportional-integral (PI) control; and
integrating a current reference value with i_{tid} and i_{tiq} to obtain an inverter voltage signal through calculation and PI control, where the inverter voltage signal and the phase output signal are input to a PWM modulation module after dq-to-abc transformation, to finally output the PWM control signal.

In a further technical solution, the outputting an active power signal based on the output three-phase voltage, the output-side current, and the phase output signal specifically includes:
performing abc-to-dq transformation on the output three-phase voltage and the phase output signal to obtain a d-axis component and a q-axis component of the output three-phase voltage;
performing abc-to-dq transformation on the output-side current and the phase output signal to obtain a d-axis component and a q-axis component of the output-side current; and
calculating based on the d-axis component and the q-axis component of the output three-phase voltage, and the d-axis component and the q-axis component of the output-side current to obtain the active power signal.

In a further technical solution, the processing the output three-phase voltage to obtain a real-time output frequency specifically includes:
performing linear abc-to-αβ coordinate transformation on the output three-phase voltage to obtain two orthogonal voltage components: v_{tg}α and v_{tg}β, and performing filtering and frequency-locking to obtain the real-time output frequency.

In a further technical solution, the obtaining the damping coefficient of the grid-forming converter based on the active power signal, the frequency output signal, and a related setting parameter specifically includes:
performing per-unitization on a difference between the output active power signal and an active power reference value, performing per-unitization on a difference between the frequency output signal and a reference frequency, and performing a division operation between the two per-unitized values to obtain the damping coefficient of the tested grid-forming converter.

In a further technical solution, the obtaining the inertia coefficient of the grid-forming converter based on the active power signal, the real-time output frequency, and a related setting parameter specifically includes:
performing per-unitization on the difference between the output active power signal and the active power reference value, performing per-unitization on a difference between the real-time output frequency and a reference frequency, performing a subtraction operation to remove an active power change part generated due to the damping coefficient, and finally performing a division operation between a result obtained through the subtraction operation and a result obtained by multiplying an output voltage frequency change rate and a coefficient, to obtain the inertia coefficient of the grid-forming converter.

According to a second aspect, an apparatus for testing an inertia coefficient and a damping coefficient of a grid-forming converter is provided, including:
a data obtaining module, configured to obtain a filter capacitor voltage in a three-phase LCL filter, an inverter-side current, an output-side current, and an output three-phase voltage;
a frequency control module, configured to output a frequency output signal and a phase output signal through frequency control;
a voltage control module, configured to: output a PWM control signal based on the phase output signal, the filter capacitor voltage, and the inverter-side current, to control turn-on time of a power semiconductor switch;
an active power measurement module, configured to output an active power signal based on the output three-phase voltage, the output-side current, and the phase output signal;
a frequency measurement module, configured to process the output three-phase voltage to obtain a real-time output frequency; and
a damping coefficient and inertia coefficient measurement module, configured to: separately process the active power signal, the real-time output frequency, and related setting parameters to obtain the inertia coefficient and the damping coefficient.

According to a third aspect, a system for testing an inertia coefficient and a damping coefficient of a grid-forming converter is provided, including:
a power semiconductor switch, a three-phase LCL filter, a three-phase alternating-current relay, and a processor, where
one terminal of the power semiconductor switch is connected to a direct-current side power source, the other terminal of the power semiconductor switch is connected to the three-phase LCL filter, and the three-phase LCL filter is connected to the tested grid-forming converter through the three-phase alternating-current relay; and
the processor is configured to: receive a filter capacitor voltage in the three-phase LCL filter, an inverter-side current, an output-side current, and an output three-phase voltage, and process the received data, and is specifically configured to:
output a frequency output signal and a phase output signal through frequency control;
output a PWM control signal based on the phase output signal, the filter capacitor voltage, and the inverter-side current, to control turn-on time of a power semiconductor switch;
output an active power signal based on the output three-phase voltage, the output-side current, and the phase output signal;
process the output three-phase voltage to obtain a real-time output frequency; and
separately process the active power signal, the real-time output frequency, and related setting parameters to obtain the inertia coefficient and the damping coefficient.

In a further technical solution, the three-phase LCL filter includes an inverter-side inductor, a grid-side inductor, and a filter capacitor, where
the inverter-side inductor, the grid-side inductor, and the filter capacitor are connected in sequence.

In a further technical solution, the inverter-side current is measured close to the inverter-side inductor; the filter capacitor voltage is measured by the filter capacitor; the output three-phase voltage is measured between the grid-side inductor and the three-phase alternating-current relay; and the output-side current is measured at an end where the three-phase alternating-current relay is connected to the tested grid-forming converter.

One or more of the above technical solutions have the following beneficial effects:

The disclosed technical solution can be used to test the inertia coefficient and the damping coefficient of the grid-forming converter without requiring complex mathematical calculations or access to parameter information inside the grid-forming converter, and is simple and effective for testing the inertia coefficient and the damping coefficient. The disclosed technical solution can be used to accurately measure the inertia coefficient and the damping coefficient of the grid-forming converter, and has high feasibility and versatility in an actual application.

The advantages of the additional aspects of the present disclosure will be partially given in the following description, and parts will become obvious from the following description, or be understood through the practice of the present disclosure.

### BRIEF DESCRIPTION OF THE DRAWINGS

Accompanying drawings of the description constitute part of the present disclosure and serve to provide further understanding of the present disclosure, and illustrative embodiments of the present disclosure and the description of the illustrative embodiments serve to explain the present disclosure and are not to be construed as unduly limiting the present disclosure.

FIG. 1 is a schematic structural diagram of an apparatus for testing an inertia coefficient and a damping coefficient of a grid-forming converter according to an embodiment of the present disclosure;

FIG. 2 is a schematic structural diagram of a frequency control module according to an embodiment of the present disclosure;

FIG. 3 is a schematic structural diagram of a voltage control module according to an embodiment of the present disclosure;

FIG. 4 is a schematic structural diagram of an active power measurement module according to an embodiment of the present disclosure;

FIG. 5 is a schematic structural diagram of a frequency measurement module according to an embodiment of the present disclosure;

FIG. 6 is a schematic structural diagram of a damping measurement module according to an embodiment of the present disclosure;

FIG. 7 is a schematic structural diagram of an inertia measurement module according to an embodiment of the present disclosure;

FIG. 8 is a schematic diagram of a damping measurement simulation result of a grid-forming converter according to an embodiment of the present disclosure; and

FIG. 9 is a schematic diagram of an inertia measurement simulation result of a grid-forming converter according to an embodiment of the present disclosure.

### DETAILED DESCRIPTION OF THE EMBODIMENTS

It should be pointed out that the following detailed description is illustrative and is intended to provide further description of the present disclosure. All technical and scientific terms used herein have the same meaning as commonly understood by those of ordinary skill in the art to which the present disclosure belongs unless otherwise defined.

It should be noted that terms used herein are merely for describing particular implementation modes and are not intended to limit illustrative implementation modes according to the present disclosure.

Embodiments of the present disclosure and features in the embodiments can be combined with each other without conflict.

### Embodiment 1

This embodiment provides a method for testing an inertia coefficient and a damping coefficient of a grid-forming converter, including the following steps.

A filter capacitor voltage in a three-phase inductor-capacitor-inductor (LCL) filter, an inverter-side current, an output-side current, and an output three-phase voltage are obtained.

A frequency output signal and a phase output signal are output through frequency control.

A pulse width modulation (PWM) control signal is output based on the phase output signal, the filter capacitor voltage, and the inverter-side current, to control turn-on time of a power semiconductor switch.

An active power signal is output based on the output three-phase voltage, the output-side current, and the phase output signal.

The output three-phase voltage is processed to obtain a real-time output frequency.

The damping coefficient of the grid-forming converter is obtained based on the active power signal, the frequency output signal, and a related setting parameter.

The inertia coefficient of the grid-forming converter is obtained based on the active power signal, the real-time output frequency, and a related setting parameter.

In this embodiment, that a frequency output signal and a phase output signal are output through frequency control specifically includes the following steps.

A frequency change rate input signal is generated by a step signal generator.

The frequency change rate input signal is integrated with a reference frequency input signal, for calculation, and both the frequency output signal and the phase output signal are obtained.

The phase output signal is used for voltage control and active power measurement, and the frequency output signal is used for measurement of the damping coefficient.

In this embodiment, that a PWM control signal is output based on the phase output signal, the filter capacitor voltage, and the inverter-side current specifically includes the following steps.

The filter capacitor voltage and the inverter-side current are sampled, and abc-to-dq transformation is performed on a sampling signal to obtain a d-axis component v_{tfd} and a q-axis component v_{tfq} of the sampled capacitor voltage, and a d-axis component i_{tid} and a q-axis component i_{tiq} of the sampled inverter-side current.
v_{tfd} and v_{tfq} are integrated with a d-axis reference value v_{tfd_ref} and a q-axis reference value v_{tfq_ref} of an input capacitor voltage, and a d-axis reference value i_{tid_ref} and a q-axis reference value i_{tiq} ref of the inverter-side current are obtained through calculation and proportional-integral (PI) control.

A current reference value is integrated with i_{tid} and i_{tiq} to obtain an inverter voltage signal through calculation and PI control, where the inverter voltage signal and the phase output signal are input to a PWM modulation module after dq-to-abc transformation, to finally output the PWM control signal.

In this embodiment, that an active power signal is output based on the output three-phase voltage, the output-side current, and the phase output signal specifically includes the following steps.
abc-to-dq transformation is performed on the output three-phase voltage and the phase output signal to obtain a d-axis component and a q-axis component of the output three-phase voltage.
abc-to-dq transformation is performed on the output-side current and the phase output signal to obtain a d-axis component and a q-axis component of the output-side current.

Calculation is performed based on the d-axis component and the q-axis component of the output three-phase voltage, and the d-axis component and the q-axis component of the output-side current to obtain the active power signal.

In this embodiment, that the output three-phase voltage is processed to obtain a real-time output frequency specifically includes the following step.

Linear abc-to-αβ coordinate transformation is performed on the output three-phase voltage to obtain two orthogonal voltage components: v_{tg}α and v_{tg}β, and filtering and frequency-locking are performed to obtain the real-time output frequency.

In this embodiment, that the damping coefficient of the grid-forming converter is obtained based on the active power signal, the frequency output signal, and a related setting parameter specifically includes the following steps.

Per-unitization is performed on a difference between the output active power signal and an active power reference value, per-unitization is performed on a difference between the frequency output signal and a reference frequency, and a division operation is performed between the two per-unitized values to obtain the damping coefficient of the tested grid-forming converter.

In this embodiment, that the inertia coefficient of the grid-forming converter is obtained based on the active power signal, the real-time output frequency, and a related setting parameter specifically includes the following step.

Per-unitization is performed on the difference between the output active power signal and the active power reference value, per-unitization is performed on a difference between the real-time output frequency and the reference frequency, a subtraction operation is performed to remove an active power change part generated due to the damping coefficient, and a division operation is finally performed between a result obtained through the subtraction operation and a result obtained by multiplying an output voltage frequency change rate and a coefficient, to obtain the inertia coefficient of the grid-forming converter.

### Embodiment 2

This embodiment is to further provide a computer device, including a memory, a processor, and a computer program stored in the memory and executable on the processor, where the computer program is executed by the processor to implement the above method.

### Embodiment 3

This embodiment is to provide a computer-readable storage medium.

The computer-readable storage medium stores a computer program thereon, where the computer program is executed by a processor to implement the steps of the foregoing method.

### Embodiment 4

This embodiment is to provides an apparatus for testing an inertia coefficient and a damping coefficient of a grid-forming converter, including a data obtaining module, a frequency control module, a voltage control module, an active power measurement module, a frequency measurement module, and a damping coefficient and inertia coefficient measurement module.

The data obtaining module is configured to obtain a filter capacitor voltage in a three-phase LCL filter, an inverter-side current, an output-side current, and an output three-phase voltage.

The frequency control module is configured to output a frequency output signal and a phase output signal through frequency control.

The voltage control module is configured to: output a PWM control signal based on the phase output signal, the filter capacitor voltage, and the inverter-side current, to control turn-on time of a power semiconductor switch.

The active power measurement module is configured to output an active power signal based on the output three-phase voltage, the output-side current, and the phase output signal.

The frequency measurement module is configured to process the output three-phase voltage to obtain a real-time output frequency.

The damping coefficient and inertia coefficient measurement module is configured to: separately process the active power signal, the real-time output frequency, and related setting parameters to obtain the inertia coefficient and the damping coefficient.

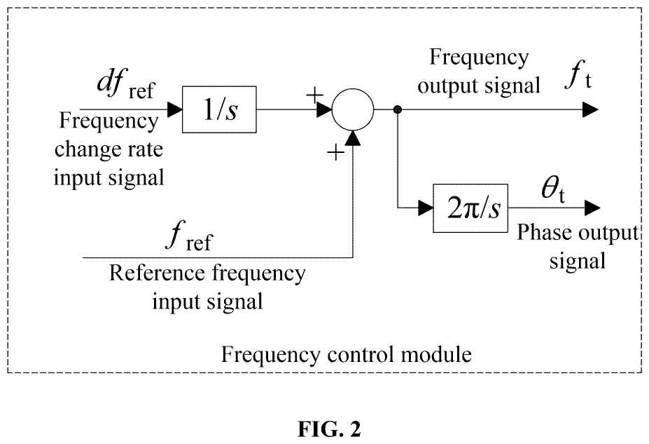

For specific modules, relate to the specific accompanying drawings. FIG. 2 shows a structure of the frequency control module. A frequency change rate input signal df_{ref} is generated by the module via a step signal generator, and is summed up with a reference frequency input signal f_{ref} after integration through an integrator to obtain a frequency output signal fₜ of the test apparatus, and the frequency output signal fₜ is multiplied by 2π/s to obtain a phase output signal θₜ. The phase output signal θₜ is used as an input signal of the voltage control module and the active power measurement module, and the frequency output signal fₜ is used as an input signal of the damping measurement module. Processing based on the frequency control module is simple and easy to operate, and is good in frequency control effect.

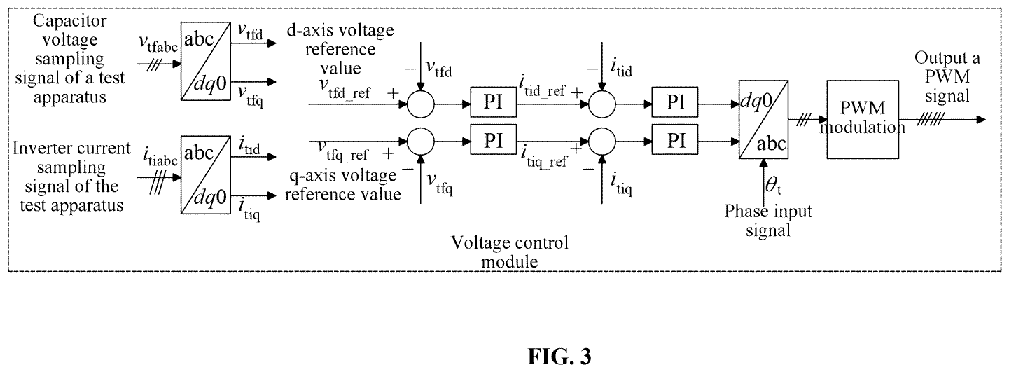

FIG. 3 shows a structure of the voltage control module. A capacitor voltage v_{tfabc} input to the test apparatus and an inverter-side current i_{tiabc} of the test apparatus are sampled by the module, and abc-to-dq transformation is performed on a sampling signal to obtain a d-axis component v_{tfd} and a q-axis component v_{tfq} of the sampled capacitor voltage of the test apparatus, and a d-axis component i_{tid} and a q-axis component i_{tiq} of the sampled inverter-side current of the test apparatus. v_{tfd} and v_{tfq} are integrated with a d-axis reference value v_{tfd_ref} and a q-axis reference value v_{tfq_ref} of an input capacitor voltage, and a d-axis reference value i_{tid_ref} and a q-axis reference value i_{tiq} ref of the inverter-side current are obtained through calculation and proportional-integral (PI) control. Then, a current reference value is integrated with i_{tid} and i_{tiq} to obtain an inverter voltage signal of the test apparatus. The inverted voltage signal and the phase output signal θₜ are input to a PWM modulation module after dq-to-abc transformation, to finally output a PWM control signal. By adjusting a PWM duty cycle output from the voltage control module, a proportion of turn-on time to turn-off time of the test apparatus is controlled, to set a frequency change rate df/dt of an output three-phase alternating-current voltage v_{tgabc} of the test apparatus. The value is determined by the frequency change rate input signal df_{ref} of the frequency control module. A three-phase voltage signal of the test apparatus can be effectively controlled by the voltage control module.

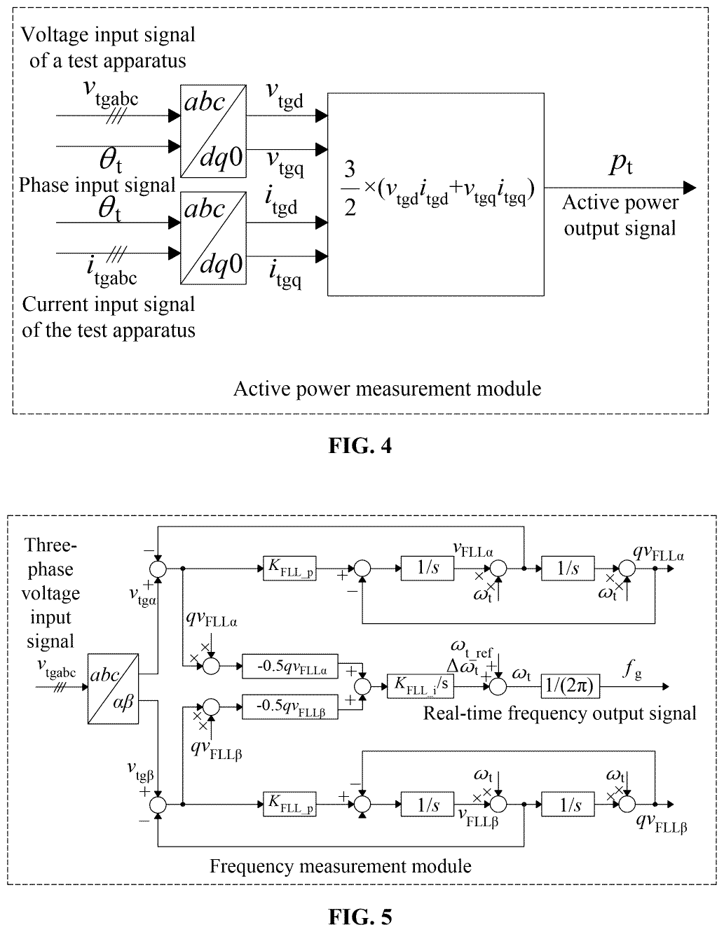

FIG. 4 shows a structure of the active power measurement module. Amplitudes of the output three-phase voltage v_{tgabc} and the three-phase current i_{tgabc} of the test apparatus are measured by the module, and an output active power pt of the test apparatus is obtained through calculation. The active power pr is used as an input signal of the damping measurement module and the inertia measurement module.

Specifically, abc-to-dq transformation is performed on the output three-phase voltage and the phase output signal to obtain a d-axis component and a q-axis component of the three-phase voltage. abc-to-dq transformation is performed on the output-side current and the phase output signal to obtain a d-axis component and a q-axis component of the output-side current. Calculation is performed based on the d-axis component and the q-axis component of the three-phase voltage, and the d-axis component and the q-axis component of the output-side current, to obtain an active power signal. A specific calculation process is as follows:

$${p}_{t} = \frac{3}{2} \times ( {v}_{tgd} \times {i}_{tgd} + {v}_{tgq} \times {i}_{tgq} ) \qquad ( 1 )$$

FIG. 5 shows a structure of the frequency measurement module. A frequency is measured by using a frequency-locked loop. This method is small in measurement error and good in frequency locking effect. An output three-phase voltage v_{tgabc} of the test apparatus is measured by the module, and linear abc-to-αβ coordinate transformation is performed to obtain two orthogonal voltage components: v_{tg}α and v_{tg}β. The v_{tg}α and v_{tg}β are respectively multiplied by a proportional gain to obtain, through second-order generalized integration, band-pass filtered and low-pass filtered coefficients v_{FLLα}, qv_{FLLα}, v_{FLLβ}, and qv_{FLLβ}. A real-time output frequency f_{g} of the test apparatus is obtained through algebraic operation and integration in FIG. 5. The output frequency f_{g} is used as an input signal of the inertia measurement module. In FIG. 5, K_{PLL_p} and K_{PLL_i} represent the proportional gain and an integral gain. v_{FLLα} and qv_{FLLα} are band-pass filtered and low-pass filtered v_{tα}. v_{FLLβ} and qv_{FLLβ} are band-pass filtered and low-pass filtered v_{tβ}.

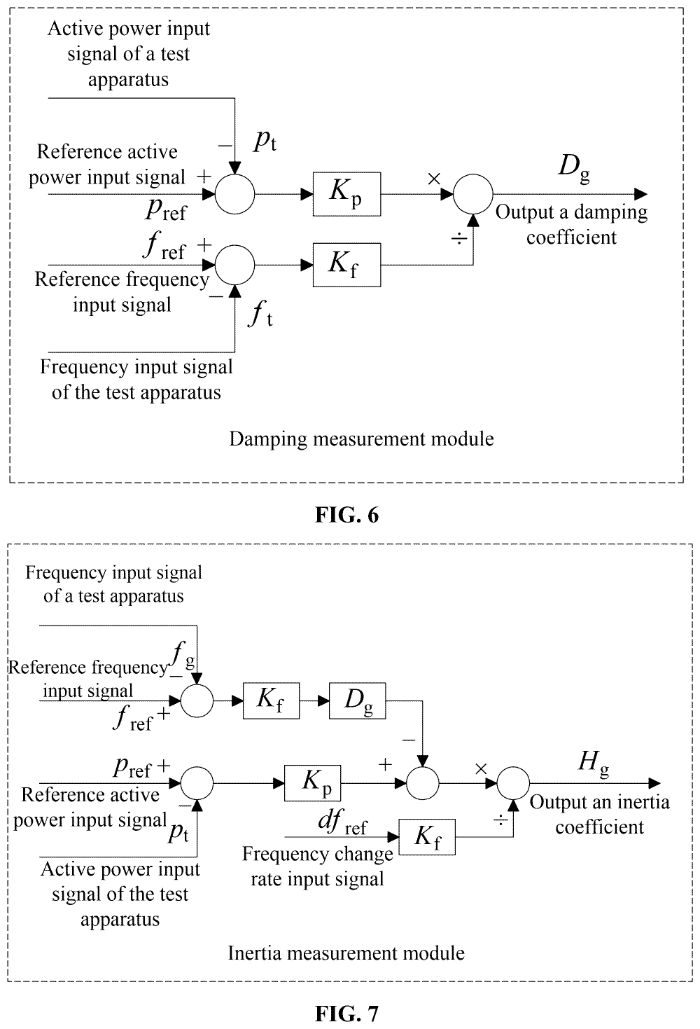

FIG. 6 shows a structure of the damping measurement module, to achieve a small calculation error. Per-unitization is performed by the module on a difference between an output active power measurement value pr and an active power reference value p_{ref} of the test apparatus, per-unitization is also performed on a difference between an output frequency fₜ and a reference frequency f_{ref} of the frequency control module, and a division operation is performed between the two per-unitized values to obtain a damping coefficient De of the tested grid-forming converter. A specific calculation process is shown in the following formula:

$${D}_{g} = [ ( {p}_{t} - {p}_{r e f} ) \times {K}_{p} ] / [ ( {f}_{t} - {f}_{r e f} ) \times {K}_{f} ] \qquad ( 2 )$$

In the formula, Kₚ and K_{f} are per-unitization gain coefficients.

FIG. 7 shows a structure of the inertia measurement module. Per-unitization is performed by the module on the difference between the output active power measurement value and the active power reference value of the test apparatus, per-unitization is also performed on a difference between the real-time output frequency of the test apparatus and a reference frequency, a subtraction operation is performed to remove an active power change part generated due to the damping coefficient D_{g}, and a division operation is finally performed between a result obtained through the subtraction operation and a result obtained by multiplying an output voltage frequency change rate df_{ref} and a coefficient K_{f}, to obtain an inertia coefficient H_{g} of the grid-forming converter. A specific calculation process is as follows:

$${H}_{g} = [ ( {p}_{t} - {p}_{ref} ) \times {K}_{p} - {D}_{g} \times ( {f}_{g} - {f}_{r e f} ) \times {K}_{f} ] / ( {df}_{r e f} \times {K}_{f} ) \qquad ( 3 )$$

The algorithm of the inertia measurement module resolves the inertia-damping coupling influence on active power, achieving brief inertia coefficient calculation, and a small calculation process.

### Embodiment 5

This embodiment is to provide a computer program product including instructions. When the computer program product runs on a computer, the computer is enabled to perform the method and the function in any one of the foregoing embodiments.

### Embodiment 6

This embodiment is to provide a system for testing an inertia coefficient and a damping coefficient of a grid-forming converter, including:
a power semiconductor switch, a three-phase LCL filter, a three-phase alternating-current relay, and a processor.

One terminal of the power semiconductor switch is connected to a direct-current side power source, the other terminal of the power semiconductor switch is connected to the three-phase LCL filter, and the three-phase LCL filter is connected to the tested grid-forming converter through the three-phase alternating-current relay.

The processor is configured to: receive a filter capacitor voltage in the three-phase LCL filter, an inverter-side current, an output-side current, and an output three-phase voltage, and process the received data, which specifically includes the following steps:

A frequency output signal and a phase output signal is output through frequency control.

A PWM control signal is output based on the phase output signal, the filter capacitor voltage, and the inverter-side current, to control turn-on time of a power semiconductor switch.

An active power signal is output based on the output three-phase voltage, the output-side current, and the phase output signal.

The output three-phase voltage is processed to obtain a real-time output frequency.

The active power signal, the real-time output frequency, and related setting parameters are separately processed to obtain the inertia coefficient and the damping coefficient.

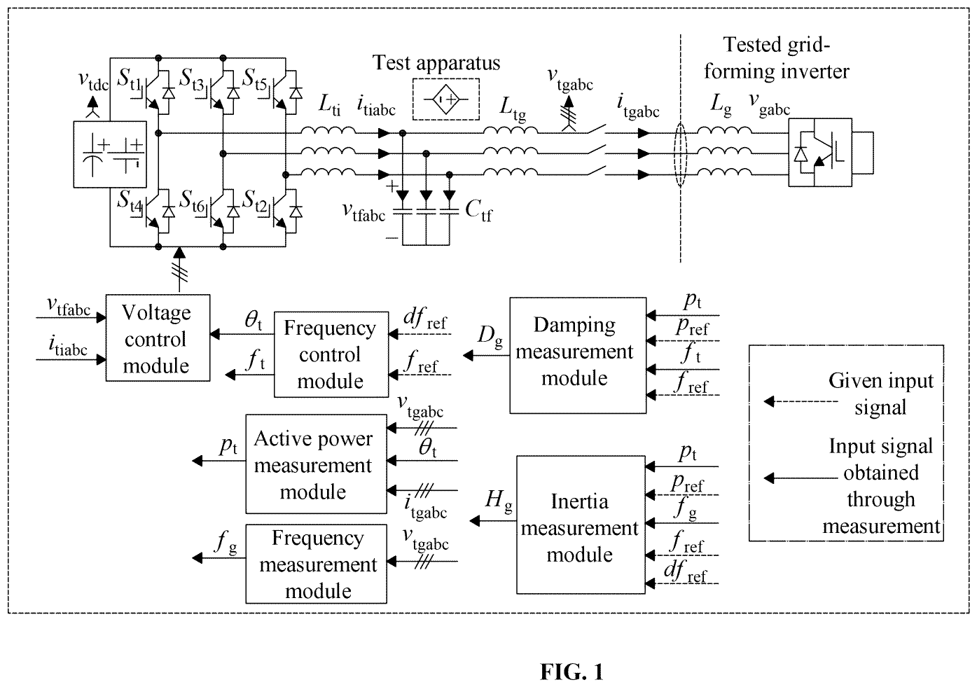

During specific implementation, FIG. 1 is a schematic structural diagram of an apparatus for testing an inertia coefficient and a damping coefficient of a grid-forming converter according to an embodiment of the present disclosure. The test apparatus includes six power semiconductor switches (Sₜ₁, Sₜ₂, Sₜ, Sₜ₄, Sₜ₅, and Sₜ₆), one three-phase LCL filter (including three inverter-side inductors Lₜᵢ, three grid-side inductors L_{tg}, and three filter capacitors C_{tf}), one three-phase alternating-current relay, a frequency control module, a voltage control module, an active power measurement module, a frequency measurement module, a damping measurement module, and an inertia measurement module. In FIG. 1, v_{tdc} is a direct-current side voltage of the test apparatus, v_{tfabc} is a capacitor voltage of the test apparatus, i_{tiabc} is an inverter-side current of the test apparatus, i_{tgabc} is an output-side current of the test apparatus, and v_{tgabc} is an output three-phase voltage of the test apparatus. An output voltage of the test apparatus is accessed to an output of the tested grid-forming converter, and an output voltage of the tested grid-forming converter is v_{gabc}.

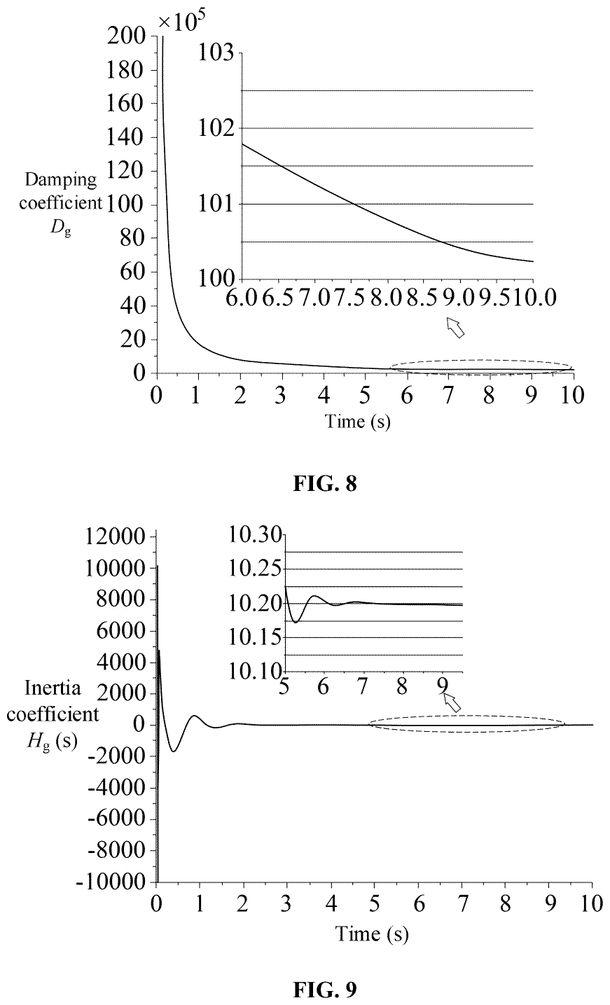

As shown in FIG. 8, in this embodiment, a damping coefficient simulation test result is about 100 that has an error less than 2% with a given value 100. Therefore, a damping coefficient of the tested grid-forming converter can be effectively measured by the test apparatus.

As shown in FIG. 9, in this embodiment, an inertia test result is about 10.2 s that has an error less than 2% with a given value 10 s. Therefore, an inertia coefficient of the tested grid-forming converter can be effective measured by the test apparatus.

The steps involved in the foregoing embodiments correspond to the method embodiment 1. For specific implementations, refer to related descriptions in Embodiment 1. The term “computer-readable storage medium” shall be understood as a single medium or a plurality of media including one or more instruction sets. It should be further understood as including any medium. The any medium can store, code, or carry a set of instructions executed by a processor, and enables the processor to perform any method in the present disclosure.

Those skilled in the art should know that the modules or steps of the disclosure may be implemented by a universal computer device. Optionally, the modules or steps may be implemented by programmable code executable by a computing device, so that the modules or steps can be stored in a storage device for execution by the computing device. Alternatively, the modules or steps may be made into integrated circuit modules respectively, or some of the modules or steps may be made into a single integrated circuit module. The present disclosure is not limited to any specific hardware and software combination.

The above describes the specific implementations of the present disclosure with reference to the accompanying drawings, but is not intended to limit the protection scope of the present disclosure. Those skilled in the art should understand that any modifications or variations made by those skilled in the art based on the technical solutions of the present disclosure without creative efforts still fall within the protection scope of the present disclosure.

What is claimed is:

1. A method for testing an inertia coefficient and a damping coefficient of a grid-forming converter, comprising:
obtaining a filter capacitor voltage in a three-phase inductor-capacitor-inductor (LCL) filter, an inverter-side current, an output-side current, and an output three-phase voltage;
outputting a frequency output signal and a phase output signal through frequency control;
outputting a pulse width modulation (PWM) control signal based on the phase output signal, the filter capacitor voltage, and the inverter-side current, to control turn-on time of a power semiconductor switch;
outputting an active power signal based on the output three-phase voltage, the output-side current, and the phase output signal;
processing the output three-phase voltage to obtain a real-time output frequency;
obtaining the damping coefficient of the grid-forming converter based on the active power signal, the frequency output signal, and a related setting parameter; and
obtaining the inertia coefficient of the grid-forming converter based on the active power signal, the real-time output frequency, and a related setting parameter.

2. The method for testing the inertia coefficient and the damping coefficient of the grid-forming converter according to claim 1, wherein the outputting the frequency output signal and the phase output signal through the frequency control comprises:
generating, by a step signal generator, a frequency change rate input signal; and
integrating the frequency change rate input signal with a reference frequency input signal for calculation, and obtaining both the frequency output signal and the phase output signal, wherein
the phase output signal is configured for voltage control and active power measurement, and the frequency output signal is configured for measurement of the damping coefficient.

3. The method for testing the inertia coefficient and the damping coefficient of the grid-forming converter according to claim 1, wherein the outputting the PWM control signal based on the phase output signal, the filter capacitor voltage, and the inverter-side current comprises:
sampling the filter capacitor voltage and the inverter-side current, and performing abc-to-dq transformation on a sampling signal to obtain a d-axis component v_{tfd} and a q-axis component v_{tfq} of a sampled filter capacitor voltage, and a d-axis component i_{tid} and a q-axis component i_{tiq} of a sampled inverter-side current;
integrating Vid and v_{tfq} with a d-axis reference value v_{tfd_ref} and a q-axis reference value v_{tfq_ref} of an input filter capacitor voltage, and obtaining a d-axis reference value i_{tid_ref} and a q-axis reference value i_{tiq_ref} of the inverter-side current through calculation and proportional-integral (PI) control; and
integrating a current reference value with i_{tid} and i_{tiq} to obtain an inverter voltage signal through calculation and PI control, wherein the inverter voltage signal and the phase output signal are input to a PWM modulation module after dq-to-abc transformation, to output the PWM control signal.

4. The method for testing the inertia coefficient and the damping coefficient of the grid-forming converter according to claim 1, wherein the outputting the active power signal based on the output three-phase voltage, the output-side current, and the phase output signal comprises:
performing abc-to-dq transformation on the output three-phase voltage and the phase output signal to obtain a d-axis component and a q-axis component of the output three-phase voltage;
performing abc-to-dq transformation on the output-side current and the phase output signal to obtain a d-axis component and a q-axis component of the output-side current; and
calculating based on the d-axis component and the q-axis component of the output three-phase voltage, and the d-axis component and the q-axis component of the output-side current to obtain the active power signal.

5. The method for testing the inertia coefficient and the damping coefficient of the grid-forming converter according to claim 1, wherein the processing the output three-phase voltage to obtain the real-time output frequency comprises:
performing linear abc-to-αβ coordinate transformation on the output three-phase voltage to obtain two orthogonal voltage components: Viga and v_{tg}β, and performing filtering and frequency-locking to obtain the real-time output frequency.

6. The method for testing the inertia coefficient and the damping coefficient of the grid-forming converter according to claim 1, wherein the obtaining the damping coefficient of the grid-forming converter based on the active power signal, the frequency output signal, and the related setting parameter comprises:
performing per-unitization on a difference between an output active power signal and an active power reference value, performing per-unitization on a difference between the frequency output signal and a reference frequency, and performing a division operation between two per-unitized values to obtain a damping coefficient of a tested grid-forming converter; and
the obtaining the inertia coefficient of the grid-forming converter based on the active power signal, the real-time output frequency, and the related setting parameter comprises:
performing per-unitization on the difference between the output active power signal and the active power reference value, performing per-unitization on a difference between the real-time output frequency and the reference frequency, performing a subtraction operation to remove an active power change part generated due to the damping coefficient, and performing a division operation between a result obtained through the subtraction operation and a result obtained by multiplying an output voltage frequency change rate and a coefficient, to obtain the inertia coefficient of the grid-forming converter.

7. An apparatus for testing an inertia coefficient and a damping coefficient of a grid-forming converter, comprising:
a data obtaining module, configured to obtain a filter capacitor voltage in a three-phase LCL filter, an inverter-side current, an output-side current, and an output three-phase voltage;
a frequency control module, configured to output a frequency output signal and a phase output signal through frequency control;
a voltage control module, configured to: output a PWM control signal based on the phase output signal, the filter capacitor voltage, and the inverter-side current, to control turn-on time of a power semiconductor switch;
an active power measurement module, configured to output an active power signal based on the output three-phase voltage, the output-side current, and the phase output signal;
a frequency measurement module, configured to process the output three-phase voltage to obtain a real-time output frequency; and
a damping coefficient and inertia coefficient measurement module, configured to: separately process the active power signal, the real-time output frequency, and related setting parameters to obtain the inertia coefficient and the damping coefficient.

8. A system for testing an inertia coefficient and a damping coefficient of a grid-forming converter, comprising:
a power semiconductor switch, a three-phase LCL filter, a three-phase alternating-current relay, and a processor, wherein
a first terminal of the power semiconductor switch is connected to a direct-current side power source, a second terminal of the power semiconductor switch is connected to the three-phase LCL filter, and the three-phase LCL filter is connected to a tested grid-forming converter through the three-phase alternating-current relay;
the processor is configured to: receive a filter capacitor voltage in the three-phase LCL filter, an inverter-side current, an output-side current, and an output three-phase voltage, and process received data, and is configured to:
output a frequency output signal and a phase output signal through frequency control;
output a PWM control signal based on the phase output signal, the filter capacitor voltage, and the inverter-side current, to control turn-on time of a power semiconductor switch;
output an active power signal based on the output three-phase voltage, the output-side current, and the phase output signal;
process the output three-phase voltage to obtain a real-time output frequency; and
separately process the active power signal, the real-time output frequency, and related setting parameters to obtain the inertia coefficient and the damping coefficient.

9. A computer device, comprising a memory, a processor, and a computer program stored in the memory and executable on the processor, wherein the processor executes the computer program to implement steps of the method according to claim 1.

10. A non-transitory computer-readable storage medium, wherein the non-transitory computer-readable storage medium stores a computer program, and the computer program is executed by a processor to implement steps of the method according to claim 1.

11. The computer device according to claim 9, wherein in the method, the outputting the frequency output signal and the phase output signal through the frequency control comprises:
generating, by a step signal generator, a frequency change rate input signal; and
integrating the frequency change rate input signal with a reference frequency input signal for calculation, and obtaining both the frequency output signal and the phase output signal, wherein
the phase output signal is configured for voltage control and active power measurement, and the frequency output signal is configured for measurement of the damping coefficient.

12. The computer device according to claim 9, wherein in the method, the outputting the PWM control signal based on the phase output signal, the filter capacitor voltage, and the inverter-side current comprises:
sampling the filter capacitor voltage and the inverter-side current, and performing abc-to-dq transformation on a sampling signal to obtain a d-axis component v_{tfd} and a q-axis component v_{tfq} of a sampled filter capacitor voltage, and a d-axis component i_{tid} and a q-axis component i_{tiq} of a sampled inverter-side current;
integrating v_{tfd} and v_{tfq} with a d-axis reference value v_{tfd} ref and a q-axis reference value v_{tfq_ref} of an input filter capacitor voltage, and obtaining a d-axis reference value i_{tid_ref} and a q-axis reference value i_{tiq} ref of the inverter-side current through calculation and proportional-integral (PI) control; and
integrating a current reference value with i_{tid} and i_{tiq} to obtain an inverter voltage signal through calculation and PI control, wherein the inverter voltage signal and the phase output signal are input to a PWM modulation module after dq-to-abc transformation, to output the PWM control signal.

13. The computer device according to claim 9, wherein in the method, the outputting the active power signal based on the output three-phase voltage, the output-side current, and the phase output signal comprises:
performing abc-to-dq transformation on the output three-phase voltage and the phase output signal to obtain a d-axis component and a q-axis component of the output three-phase voltage;
performing abc-to-dq transformation on the output-side current and the phase output signal to obtain a d-axis component and a q-axis component of the output-side current; and
calculating based on the d-axis component and the q-axis component of the output three-phase voltage, and the d-axis component and the q-axis component of the output-side current to obtain the active power signal.

14. The computer device according to claim 9, wherein in the method, the processing the output three-phase voltage to obtain the real-time output frequency comprises:
performing linear abc-to-αβ coordinate transformation on the output three-phase voltage to obtain two orthogonal voltage components: v_{tg}α and v_{tg}β, and performing filtering and frequency-locking to obtain the real-time output frequency.

15. The computer device according to claim 9, wherein in the method, the obtaining the damping coefficient of the grid-forming converter based on the active power signal, the frequency output signal, and the related setting parameter comprises:
performing per-unitization on a difference between an output active power signal and an active power reference value, performing per-unitization on a difference between the frequency output signal and a reference frequency, and performing a division operation between two per-unitized values to obtain a damping coefficient of a tested grid-forming converter; and
the obtaining the inertia coefficient of the grid-forming converter based on the active power signal, the real-time output frequency, and the related setting parameter comprises:
performing per-unitization on the difference between the output active power signal and the active power reference value, performing per-unitization on a difference between the real-time output frequency and the reference frequency, performing a subtraction operation to remove an active power change part generated due to the damping coefficient, and performing a division operation between a result obtained through the subtraction operation and a result obtained by multiplying an output voltage frequency change rate and a coefficient, to obtain the inertia coefficient of the grid-forming converter.

16. The non-transitory computer-readable storage medium according to claim 10, wherein in the method, the outputting the frequency output signal and the phase output signal through the frequency control comprises:
generating, by a step signal generator, a frequency change rate input signal; and
integrating the frequency change rate input signal with a reference frequency input signal for calculation, and obtaining both the frequency output signal and the phase output signal, wherein
the phase output signal is configured for voltage control and active power measurement, and the frequency output signal is configured for measurement of the damping coefficient.

17. The non-transitory computer-readable storage medium according to claim 10, wherein in the method, the outputting the PWM control signal based on the phase output signal, the filter capacitor voltage, and the inverter-side current comprises:
sampling the filter capacitor voltage and the inverter-side current, and performing abc-to-dq transformation on a sampling signal to obtain a d-axis component v_{tfd} and a q-axis component v_{tfq} of a sampled filter capacitor voltage, and a d-axis component i_{tid} and a q-axis component i_{tiq} of a sampled inverter-side current;
integrating v_{tfd} and v_{tfq} with a d-axis reference value v_{tfd_ref} and a q-axis reference value v_{tfq_ref} of an input filter capacitor voltage, and obtaining a d-axis reference value i_{tid_ref} and a q-axis reference value i_{tiq_ref} of the inverter-side current through calculation and proportional-integral (PI) control; and
integrating a current reference value with i_{tid} and i_{tiq} to obtain an inverter voltage signal through calculation and PI control, wherein the inverter voltage signal and the phase output signal are input to a PWM modulation module after dq-to-abc transformation, to output the PWM control signal.

18. The non-transitory computer-readable storage medium according to claim 10, wherein in the method, the outputting the active power signal based on the output three-phase voltage, the output-side current, and the phase output signal comprises:
performing abc-to-dq transformation on the output three-phase voltage and the phase output signal to obtain a d-axis component and a q-axis component of the output three-phase voltage;
performing abc-to-dq transformation on the output-side current and the phase output signal to obtain a d-axis component and a q-axis component of the output-side current; and
calculating based on the d-axis component and the q-axis component of the output three-phase voltage, and the d-axis component and the q-axis component of the output-side current to obtain the active power signal.

19. The non-transitory computer-readable storage medium according to claim 10, wherein in the method, the processing the output three-phase voltage to obtain the real-time output frequency comprises:
performing linear abc-to-αβ coordinate transformation on the output three-phase voltage to obtain two orthogonal voltage components: v_{tg}α and v_{tg}β, and performing filtering and frequency-locking to obtain the real-time output frequency.

20. The non-transitory computer-readable storage medium according to claim 10, wherein in the method, the obtaining the damping coefficient of the grid-forming converter based on the active power signal, the frequency output signal, and the related setting parameter comprises:
performing per-unitization on a difference between an output active power signal and an active power reference value, performing per-unitization on a difference between the frequency output signal and a reference frequency, and performing a division operation between two per-unitized values to obtain a damping coefficient of a tested grid-forming converter; and
the obtaining the inertia coefficient of the grid-forming converter based on the active power signal, the real-time output frequency, and the related setting parameter comprises:
performing per-unitization on the difference between the output active power signal and the active power reference value, performing per-unitization on a difference between the real-time output frequency and the reference frequency, performing a subtraction operation to remove an active power change part generated due to the damping coefficient, and performing a division operation between a result obtained through the subtraction operation and a result obtained by multiplying an output voltage frequency change rate and a coefficient, to obtain the inertia coefficient of the grid-forming converter.
